(19) United States
(12) Patent Application Publication
(10) Pub. No.: US 2025/0120143 A1
(43) Pub. Date: Apr. 10, 2025

(54) EXTENDED DRAIN TRANSISTOR FOR HIGH VOLTAGE APPLICATIONS

(71) Applicant: Intel Corporation, Santa Clara, CA (US)

(72) Inventors: Sanjay Rangan, Albuquerque, NM (US); Adam Brand, Mountain View, CA (US); Chen-Guan Lee, Portland, OR (US); Rahul Ramaswamy, Portland, OR (US); Hsu-Yu Chang, Hillsboro, OR (US); Adithya Shankar, Hillsboro, OR (US); Marko Radosavljevic, Portland, OR (US)

(73) Assignee: Intel Corporation, Santa Clara, CA (US)

(21) Appl. No.: 18/482,192

(22) Filed: Oct. 6, 2023

(51) Int. Cl. H01L 29/08; H01L 27/092; H01L 29/06; H01L 29/417; H01L 29/423; H01L 29/775

(52) U.S. Cl. CPC H10D 62/151; H10D 30/43; H10D 30/6729; H10D 30/6735; H10D 62/121; H10D 84/856

(57) ABSTRACT

Described herein are gate-all-around (GAA) transistors with extended drains, where the drain region extends through a well region below the GAA transistor. A high voltage can be applied to the drain, and the extended drain region provides a voltage drop. The transistor length (and, specifically length of the extended drain) can be varied based on the input voltage to the device, e.g., providing a longer drain for higher input voltages. The extended drain transistors can be implemented in devices that include CFETs, either by implementing the extended drain transistor across both CFET layers, or by providing a sub-fin pedestal with the well regions in the lower layer.

### BACKGROUND

Non-planar transistors are three-dimensional electronic devices that deviate from a traditional flat transistor design. Compared to planar transistors, non-planar transistors can provide improved control over current flow, reduced leakage, and enhanced performance, making it a key technology for smaller, faster, and more energy-efficient electronic devices. Examples of non-planar transistors include fin-shaped field effect transistors, referred to as FinFETs, and gate-all-around (GAA) transistors.

GAA transistors, also referred to as surrounding-gate transistors, have a gate material that surrounds a channel region on all sides. GAA transistors may be nanoribbon-based or nanowire-based. In a nanoribbon transistor, a gate stack that may include one or more gate electrode materials and a gate dielectric may be provided around a portion of an elongated semiconductor structure called “nanoribbon”, forming the gate stack on all sides of the nanoribbon. A source region and a drain region can be provided on the opposite ends of the channel (e.g., the nanoribbon(s), or nanowire(s)) and on either side of the gate stack, forming, respectively, a source and a drain of such a transistor.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a cross-section across a GAA transistor showing the source, gate, and drain, according to some embodiments of the present disclosure.

FIG. 1B is a cross-section of the GAA transistor through the plane AA′ in FIG. 1A, according to some embodiments of the present disclosure.

FIG. 2 is cross-section of a GAA transistor formed over an n-well and a p-well, according to some embodiments of the present disclosure.

FIG. 3 is a cross-section of a GAA transistor with an extended drain, according to some embodiments of the present disclosure.

FIG. 4 is a cross-section of a GAA transistor with an extended drain and additional dummy regions, according to some embodiments of the present disclosure.

FIGS. 5A-C illustrate different cross-sections through several transistors in a CFET device, according to some embodiments of the present disclosure.

FIG. 6 is a cross-section of a GAA transistor with an extended drain that may be formed across multiple layers in a CFET device, according to some embodiments of the present disclosure.

FIG. 7 is a cross-section of a GAA transistor with an extended drain that may be formed over a fin pedestal in a CFET device, according to some embodiments of the present disclosure.

FIG. 8 is a cross-section illustrating the GAA transistor of FIG. 7 alongside a CFET stack, according to some embodiments of the present disclosure.

FIGS. 9A and 9B are top views of a wafer and dies that include one or more extended drain transistors in accordance with any of the embodiments disclosed herein.

FIG. 10 is a cross-sectional side view of an IC device that may include one or more extended drain transistors in accordance with any of the embodiments disclosed herein.

FIG. 11 is a cross-sectional side view of an IC device assembly that may include extended drain transistors in accordance with any of the embodiments disclosed herein.

FIG. 12 is a block diagram of an example computing device that may include one or more extended drain transistors in accordance with any of the embodiments disclosed herein.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

Described herein are integrated circuit (IC) devices that include GAA transistors, such as nanoribbon-based transistor, that have extended drains. GAA transistors provide several advantages over other transistor architectures, such as planar transistor architectures. For example, GAA transistors provide improved electrostatic transistor control and faster transistor speeds relative to other transistor architectures. For certain applications, nanoribbon-based channels are particularly advantageous, providing increased drive current at smaller scales relative to other non-planar architectures.

Transistors typically include a gate stack coupled to a semiconductor channel, such as a nanoribbon or a stack of nanoribbons. A gate stack includes a gate electrode and a gate dielectric, with the gate dielectric formed between the gate electrode and the channel material. In a nanoribbon transistor, the gate dielectric is formed around each nanoribbon, and the gate electrode is formed over and around the gate dielectric, including in spaces between adjacent nanoribbons in the stack. A source region is formed at one end of the fin or nanoribbons, and a drain region is formed at the opposite end of the fin or nanoribbons, thus realizing a three-terminal device.

One challenge in current nanoribbon transistors is adapting nanoribbon-based devices to high input voltages. GAA transistors are generally suited for relatively low voltages, and applying a high voltage to a GAA transistor can lead to breakdown or degradation. Previous solutions to lowering input voltages for GAA devices include using downconverters, such as capacitor-based or inductor-based voltage converters, which consume a large area in an electronic device. Another option is to use implant doping in the nanoribbon channel region to manage the channel resistance. However, implant doping is not scalable to allow for different input voltages within a device, and may not be sufficient for large input voltages.

As disclosed herein, extended drain architectures implemented over a sub-fin are disclosed. One or more dummy gates, dummy drains, and additional channel length are provided, to extend the drain out from a standard position. The GAA transistor is formed over semiconductor well regions, where the well doping matches the channel and source/drain regions formed over the wells. Current travels along the well between the extended drain and the gate region, and resistance in the well downconverts the input voltage at the drain to a lower voltage at the gate region.

In some embodiments, the extended drain transistor includes, at one end, a source region and a gate region, coupled to a respective source contact and a gate contact, and each formed around a channel region (e.g., one or more nanoribbon channels). At least one dummy gate and dummy drain are formed around another portion of the channel region that extends from the gate region in a direction opposite the source region. An extended drain region is coupled to the channel region at an opposite end from the source region. The extended drain region, as well as the dummy gate and dummy drain, are formed over a semiconductor well (e.g., an n-well in an n-type metal-oxide-semiconductor (NMOS) device).

In some embodiments, extended drain transistors are implemented in a device that includes complementary field-effect-transistors (CFETs). A CFET is a type of transistor configuration that combines both N-channel and P-channel field-effect transistors (FETs) within the same circuit. This design allows for efficient digital and analog circuitry, especially in complementary metal-oxide-semiconductor (CMOS) technology. In a CFET arrangement, the N-channel FET may operate as an enhancement mode transistor, while the P-channel FET may operate as a depletion mode transistor. When used together, these transistors complement each other's behavior. CFETs may be employed in digital logic gates, memory cells, and various ICs. The complementary nature of CFETs may reduce power consumption and/or enhance overall circuit performance in modern electronic devices.

When a CFET architecture is used, a layer of NMOS devices may be stacked over a layer of p-type metal-oxide-semiconductor (PMOS) devices, or vice versa. The CFET transistors may have a non-planar transistor architecture, e.g., the transistors may be FinFETs, GAA transistors, nanoribbon transistors, nanowire transistors, or another transistor architecture. In some cases, individual transistors may be aligned and stacked, e.g., an NMOS transistor in the NMOS layer may be stacked over a PMOS transistor in the PMOS layer. A pair of transistors (e.g., a stacked NMOS and PMOS transistor) may be coupled together in a circuit, e.g., connected in parallel or in series with each other.

To implement an extended drain transistor in a device that also includes CFETs, the extended drain transistor may extend through both layers used for the CFET devices. However, the extended drain transistor may have consistent doping across the layers, as opposed to the CFET stacks which have NMOS on a lower layer and PMOS on an upper layer, or vice versa. In another embodiment, the lower layer is used to provide a pedestal sub-fin, where the sub-fins for forming the semiconductor wells are formed in the lower layer, and a nanoribbon transistor with an extended drain is formed in the upper layer.

The extended drain transistors described herein may be implemented in one or more components associated with an IC. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well known features are omitted or simplified in order not to obscure the illustrative implementations.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.”

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. The terms “substantially,” “close,” “approximately,” “near,” and “about,” generally refer to being within +/−20% of a target value, unless specified otherwise. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “logic state” of a ferroelectric memory cell refers to one of a finite number of states that the cell can have, e.g. logic states “1” and “0,” each state represented by a different polarization of the ferroelectric material of the cell. In another example, as used herein, a “READ” and “WRITE” memory access or operations refer to, respectively, determining/sensing a logic state of a memory cell and programming/setting a logic state of a memory cell. In other examples, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. In yet another example, a “high-k dielectric” refers to a material having a higher dielectric constant (k) than silicon oxide. The terms “oxide,” “carbide,” “nitride,” etc. refer to compounds containing, respectively, oxygen, carbon, nitrogen, etc.

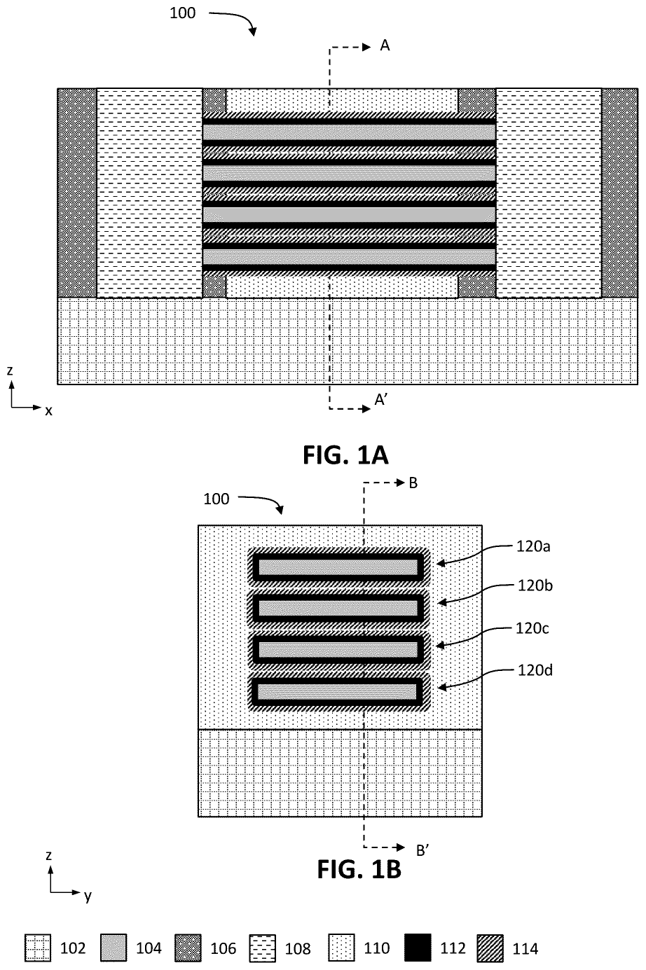

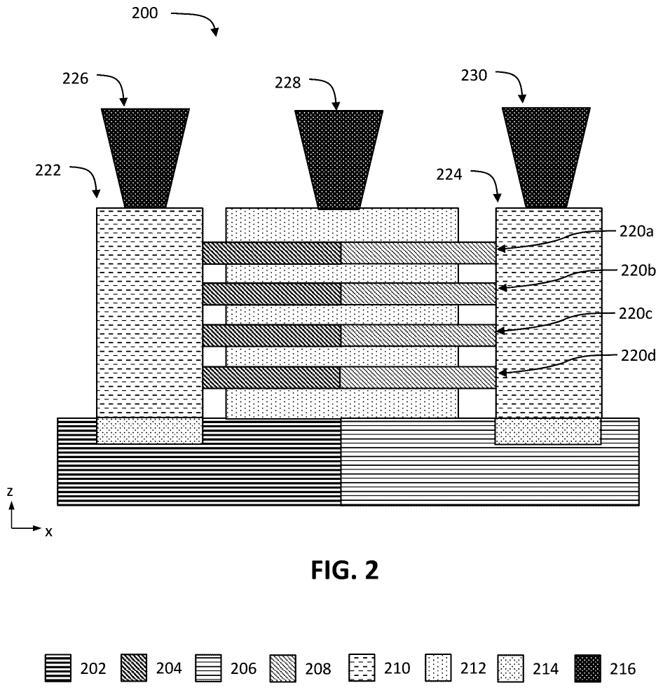

For convenience, if a collection of drawings designated with different letters are present, e.g., FIGS. 1A-1B, such a collection may be referred to herein without the letters, e.g., as “FIG. 1.”

### Example GAA Transistor

FIGS. 1A-1B illustrate an example architecture of a nanoribbon-based transistor. FIG. 1A is a cross-section across a transistor 100 showing the source, gate, and drain. FIG. 1B is a cross-section across the gate regions of the transistor 100. FIG. 1B is a cross-section through the plane AA′ in FIG. 1A, and FIG. 1A is a cross-section through the plane BB′ in FIG. 1B.

A number of elements referred to in the description of FIGS. 1A and 1B with reference numerals are illustrated in these figures with different patterns, with a legend at the bottom of the page showing the correspondence between the reference numerals and patterns. The legend illustrates that FIGS. 1A and 1B use different patterns to show a support structure 102, a channel material 104, a dielectric material 106, a source or drain (S/D) region 108, a gate electrode 110, an oxide 112, and a high-k dielectric 114.

In the drawings, some example structures of various devices and assemblies described herein are shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

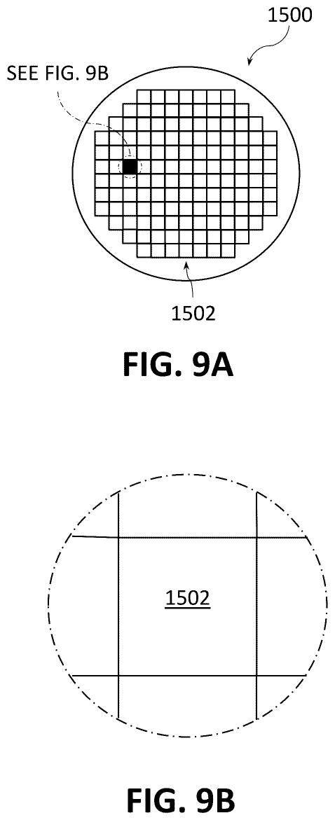

In general, implementations of the present disclosure may be formed or carried out on a support structure, e.g., the support structure 102 illustrated in FIG. 1. The support structure 102 may be, e.g., a substrate, a die, a wafer or a chip. For example, the support structure may be the wafer 1500 of FIG. 9A, discussed below, and may be, or be included in, a die, e.g., the singulated die 1502 of FIG. 9B, discussed below. The support structure 102 extends along the x-y plane in the coordinate system shown in FIG. 1.

In some embodiments, the support structure may be a substrate that includes silicon and/or hafnium. More generally, the support structure may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group Ill-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support structure may be a printed circuit board (PCB) substrate. Although a few examples of materials from which the substrate may be formed are described here, any material that may serve as a foundation upon which a semiconductor device including one or more nanoribbon transistors, as described herein, may be built falls within the spirit and scope of the present disclosure.

In FIGS. 1A and 1B, a transistor 100 is formed over a support structure 102. The transistor 100 includes a channel material 104 formed into four nanoribbons stacked on top of each other. The channel material 104 may be a semiconductor, such as silicon or other semiconductor materials described herein. For example, the channel material 104 may be composed of semiconductor material systems including, for example, N-type or P-type materials systems. In other embodiments, the channel material 104 may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. The channel material 104 may include one or more of cobalt oxide, copper oxide, ruthenium oxide, nickel oxide, niobium oxide, copper peroxide, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc.

In some embodiments, multiple channel materials may be included within an IC device. For example, an IC device may include both NMOS transistors and PMOS transistors, e.g., alternating rows of NMOS and PMOS transistors. NMOS and PMOS logic can use different groups of channel material 104, e.g., silicon may be used to form an n-type semiconductor channel, while silicon germanium may be used as to form a p-type semiconductor channel. In some embodiments, a single channel material 104 is used (e.g., silicon), and different portions (e.g., channel material to form different transistors) may include different dopants, e.g., n-type dopants for NMOS transistors and p-type dopants for PMOS transistors.

The transistor 100 includes nanoribbons 120a, 120b, 120c, and 120d, referred to collectively as nanoribbons 120 or individually as a nanoribbon 120. Each nanoribbon 120 is at a different height in the z-direction in the orientation shown in FIGS. 1A and 1B, i.e., a different distance from the support structure 102, where the nanoribbon 120a is the greatest distance from the support structure 102, and the nanoribbon 120d is the shortest distance from the support structure 102. In other embodiments, nanoribbon-based transistors may have fewer nanoribbons (e.g., one, two, or three nanoribbons), or more than four nanoribbons (e.g., five nanoribbons, six nanoribbons, etc.). The nanoribbons 120 each have an elongated structure that extends over the support structure 102. Each nanoribbon 120 extends primarily in the x-direction in the coordinate system used in FIG. 1. The direction in which the nanoribbons 120 extend is parallel to the support structure 102.

S/D regions 108a and 108b are formed at either end of the nanoribbon channels 120, as illustrated in FIG. 1A. The S/D regions 108 may be formed from one or more layers of doped semiconductors, metals, metal alloys, or other materials. In some embodiments described herein, the S/D regions 108 may include a doped semiconductor, such as silicon or another semiconductor doped with an N-type dopant or a P-type dopant. In some embodiments, the S/D regions 108 may include multiple layers with different levels of conductivity, e.g., a doped semiconductor followed by a more highly doped semiconductor, or a semiconductor followed by metal. In some embodiments, the S/D regions 108 may be formed using an epitaxial deposition process.

A central portion of each of the nanoribbon channels 120 is surrounded by a gate electrode 110. A gate dielectric surrounds the nanoribbon channels 120 under the gate electrodes 110. In this example, the gate dielectric around each nanoribbon channel 120 includes a layer of an oxide 112 and a layer of a high-k dielectric 114. The oxide 112 is grown directly on the nanoribbon channels 120, and the high-k dielectric 114 surrounds the oxide 112.

The gate electrode 110 may be a conductive material, such as a metal. The gate electrode 110 may include at least one P-type work function metal or N-type work function metal. For a PMOS transistor, metals that may be used for the gate electrode 110 may include, but are not limited to, ruthenium, palladium, platinum, cobalt, nickel, and conductive metal oxides (e.g., ruthenium oxide). For an NMOS transistor, metals that may be used for the gate electrode 110 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode 110 may include a stack of two or more metal layers, where one or more metal layers are work function metal layers and at least one metal layer is a fill metal layer.

The high-k dielectric 114 may include elements such as hafnium, silicon, oxygen, titanium, tantalum, lanthanum, aluminum, zirconium, barium, strontium, yttrium, lead, scandium, niobium, and zinc. Examples of high-k materials that may be used in the high-k dielectric 114 include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

Regions of the nanoribbon channels 120 not surrounded by the oxide 112, high-k dielectric 114, and gate electrode 110, or by an S/D regions 108, are filled in with a dielectric material 106. The dielectric material 106 may be a low-k or high-k dielectric including, but not limited to, elements such as hafnium, silicon, oxygen, nitrogen, titanium, tantalum, lanthanum, aluminum, zirconium, barium, strontium, yttrium, lead, scandium, niobium, and zinc. Further examples of dielectric materials 106 include, but are not limited to silicon nitride, silicon oxide, silicon dioxide, silicon carbide, silicon nitride doped with carbon, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate.

Example GAA Transistor with Doped Wells

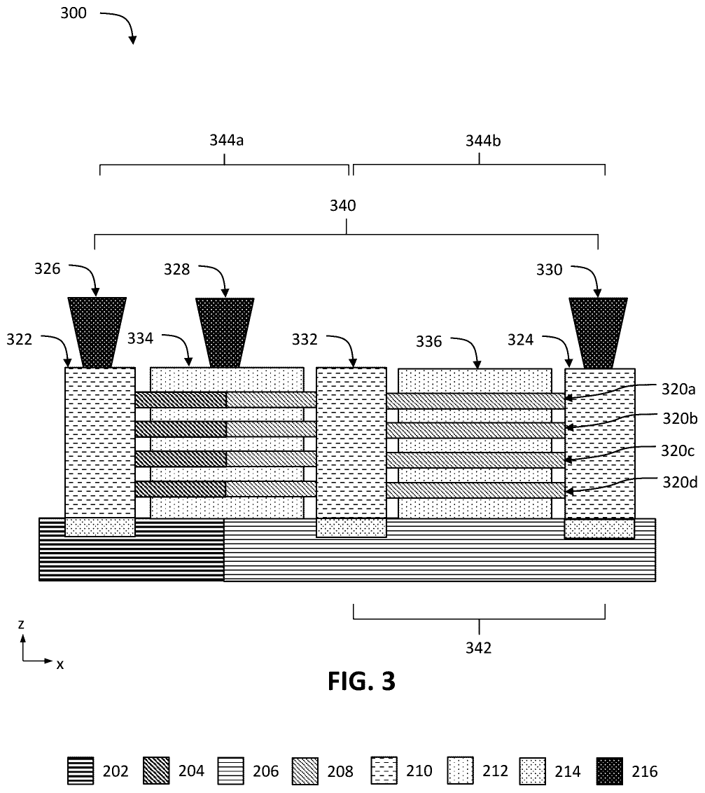

FIG. 2 is cross-section of a GAA transistor formed over a pair of doped wells, e.g., an n-well and a p-well. FIG. 2 is a cross-section across a transistor 200 showing the source, gate, and drain. A number of elements referred to in the description of FIGS. 2-4 and 6-8 with reference numerals are illustrated in these figures with different patterns, with a legend at the bottom of the page showing the correspondence between the reference numerals and patterns. For example, the legend illustrates that FIG. 2 uses different patterns to show a first well 202 (e.g., a P-well), a first channel material 204 (e.g., a P-doped channel material), a second well 206 (e.g., an N-well), a second channel material 208 (e.g., an N-doped channel material), a S/D region 210, a gate stack 212, a seed material 214, and a conductive material 216.

The transistor 200 includes four nanoribbons 220a, 220b, 220c, and 220d, which have similar structures to the nanoribbons 120a, 120b, 120c, and 120d shown in FIG. 1. The nanoribbons 220 include a semiconductor material (e.g., silicon), and different sides of the semiconductor material are doped with different dopants, resulting in the first channel material 204 on the left side of the nanoribbons 220 (in the orientation of FIG. 2), and the second channel material 208 on the right side of the nanoribbons 220. For example, the first channel material 204 may be silicon doped with boron or another p-type dopant, and the second channel material 208 may be silicon doped with phosphorous, arsenic, or another n-type dopant.

The portions of the nanoribbons 220 that include the first channel material 204 are over the first well 202, and the portions of the nanoribbons 220 that include the second channel material 208 are over the second well 206. The first well 202 and the second well 206 may include a semiconductor material, such as silicon. The first well 202 may further include the same dopant (e.g., boron) as the first channel material 204, and the second well 206 may further include the same dopant (e.g., phosphorous or arsenic) as the second channel material 208. The first well 202 and the first channel material 204 may be doped in a first process (during which the second well 206 and second channel material 208 are blocked), and the second well 206 and the second channel material 208 may be doped in a second process (during which the first well 202 and the first channel material 204 are blocked). While not specifically shown, the wells 202 and 206 and the transistor 200 may be formed over a support structure, e.g., the support structure 102. For example, the wells 202 and 206 may be formed within and/or over the support structure 102.

A first S/D region 222 is formed at a first end of the nanoribbons 220 and a second S/D region 224 is formed at a second end of the nanoribbons 220, opposite the first end and first S/D region 222. The S/D regions 222 and 224 may be similar to the S/D regions 108 described with respect to FIG. 1. In this example, the S/D regions 222 and 224 are formed over a seed material 214 embedded in the wells 202 and 206. The seed material 214 may form nuclei or templates for subsequent steps in forming the S/D regions 222 and 224. The seed material 214 forming the seed regions may be doped with the desired conductivity type (P-type or N-type) for the S/D regions 222 and 224.

A gate stack 212 is formed over a central portion of the nanoribbons 220. The gate stack 212 may include one or more layers of a gate dielectric, e.g., the oxide 112 and high-k dielectric 114 shown in FIG. 1. The gate stack 212 further includes a gate electrode, which may be similar to the gate electrode 110 shown in FIG. 1. The gate stack 212 may be deposited after the nanoribbons and wells are doped.

Conductive contacts 226, 228, and 230 are coupled to the S/D region 222, the gate stack 212, and the S/D region 224, respectively. The conductive contacts 226, 228, and 230 are each formed from a conductive material 216, which may be a metal or another conductor. While the conductive contacts 226, 228, and 230 are all shown on an upper side of the transistor 200, in other embodiments, one or more of the conductive contacts 226, 228, and 230 may be backside contacts or have other arrangements. Furthermore, while each of the conductive contacts 226, 228, and 230 are shown as including the same material 216, in some embodiments, different contacts may include different materials.

Example GAA Transistors with Extended Drain

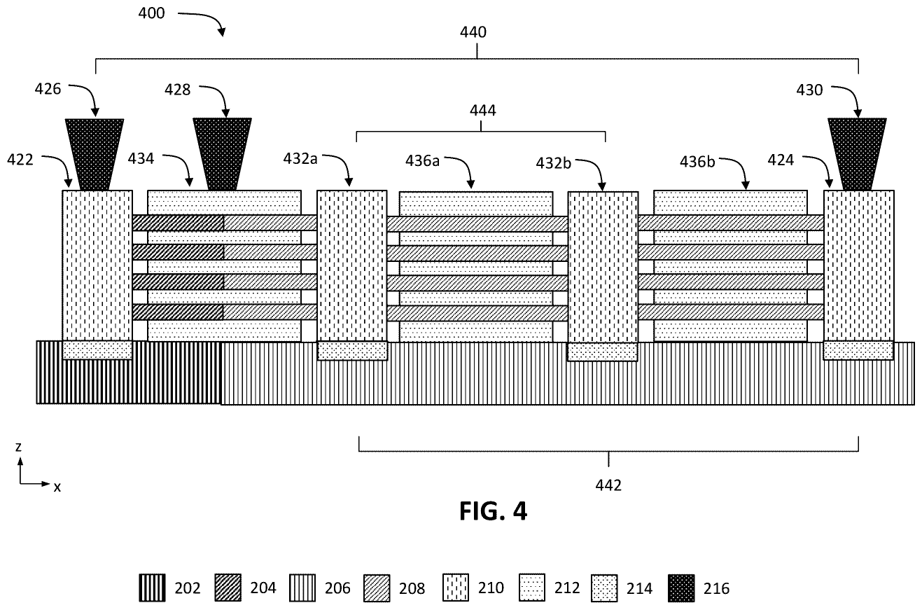

FIG. 3 is a cross-section of a GAA transistor with an extended drain, according to some embodiments of the present disclosure. The transistor 300 includes four nanoribbons 320a, 320b, 320c, and 320d. The nanoribbons 320 have similar structures to the nanoribbons 120 and 220, except that they are longer than the nanoribbons 120 and 220. The nanoribbons 320 include the first channel material 204 on the left side of the nanoribbons 320 (in the orientation of FIG. 3), and the second channel material 208 on the right side of the nanoribbons 320. The portion of the nanoribbons 320 that includes the first channel material 204 is shorter than the portion of the nanoribbons 320 that includes the second channel material 208.

The transistor 300 is formed over the first well 202 and the second well 206, e.g., a p-well and an n-well, as described with respect to FIG. 2. The portions of the nanoribbons 320 that includes the first channel material 204 are over the first well 202, and the portions of the nanoribbons 320 that include the second channel material 208 are over the second well 206. The nanoribbons 320 and wells 202 and 206 may be doped as described with respect to FIG. 2.

A first S/D region 322 is at a first end of the nanoribbons 320 and a second S/D region 324 is at a second end of the nanoribbons 320, opposite the first end and first S/D region 322. The S/D regions 322 and 324 may be similar to the S/D regions 108 described with respect to FIG. 1 and the S/D regions 322 and 324 described with respect to FIG. 2. In addition, a third S/D region 332 is between the first S/D region 322 and 324, along a central portion of the nanoribbons 320. While not specifically illustrated, the nanoribbons 320 may extend through the third S/D region 332, i.e., the S/D material 210 is deposited around the nanoribbons 320 to form the third S/D region 332. Likewise, the first and second S/D regions 222 and 224 may be deposited around the ends of the nanoribbons 320. Like the S/D regions 222 and 224 in FIG. 2, the S/D regions 322, 324, and 332 are formed over a seed material 214 embedded in the wells 202 and 206.

Two gate stacks 212 are formed over the nanoribbons 320. A first gate stack 334 is formed over the nanoribbons 320, in a region between the S/D region 322 and the S/D region 332. A second gate stack 336 is formed over the nanoribbons 320, in a region between the S/D region 332 and the S/D region 324. Each of the gate stacks 334 and 336 may include one or more layers of a gate dielectric, e.g., the oxide 112 and high-k dielectric 114 shown in FIG. 1, and a gate electrode, which may be similar to the gate electrode 110 shown in FIG. 1.

Conductive contacts 326, 328, and 330 are coupled to the first S/D region 322, the first gate stack 334, and the second S/D region 324, respectively. The conductive contacts 326, 328, and 330 include the conductive material 216, and they may be similar to the conductive contacts 226, 228, and 230 described with respect to FIG. 2.

The third S/D region 332 is not coupled to a conductive contact. The second gate 336 is also not coupled to a conductive contacts. These may be considered a dummy S/D region 332 and a dummy gate 336, or a floating S/D region 332 and a floating gate 336. The voltage on the third S/D region 332 and the voltage on the second gate 336 are not controlled. Instead, current flow through the transistor 300 is controlled by the contacts 326, 328, and 330. The second S/D region 324 is physically separated from the first S/D region 322 and the active gate 334, and thus forms an extended S/D region, or (if the S/D region 324 is a drain) an extended drain. The region 342 of the transistor 300 may be considered an extended drain region.

When a voltage is applied to the conductive contact 330, current may flow through the S/D region 324, the second well 206, and the third S/D region 332. In other words, current may flow through the second well 206 in the extended drain region 342. In some cases, current may not flow through the nanoribbons 320 in the region 342, or a minimal amount of current may flow through the nanoribbons 320 in the region 342.

The transistor 300 may have a length 340, where the length 340 is measured from the first S/D region 322 (e.g., the center of the first S/D region 322) to the second S/D region 324 (e.g., the center of the second S/D region 324). The length 340 may be, for example, at least 100 nanometers, at least 150 nanometers, at least 200 nanometers, at least 300 nanometers, at least 400 nanometers, or a different length. In addition, FIG. 3 illustrates unit lengths 344a and 344b, where each unit length 344 is a length of one “unit” of the transistor 300 between adjacent S/D regions (e.g., from the S/D region 322 to the dummy S/D region 332, and from the dummy S/D region 332 to the S/D region 324). Each unit length 344 may be, e.g., at least 50 nanometers, at least 70 nanometers, at least 100 nanometers, at least 150 nanometers, at least 200 nanometers, etc. For example, each unit length 344 may be between 60 and 200 nanometers.

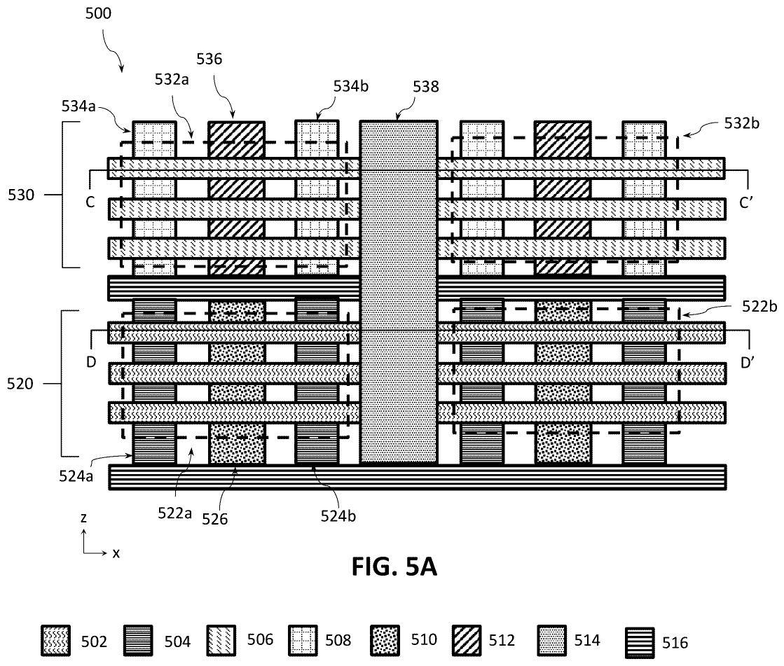

While an extended drain region that includes one dummy gate and one additional S/D region is illustrated in FIG. 3, additional dummy gates and S/D regions may be included in a transistor to further extend the drain region. FIG. 4 is a cross-section of a GAA transistor 400 with an extended drain and additional dummy regions, according to some embodiments of the present disclosure. The transistor 400 includes four nanoribbons, similar to the nanoribbons 320 of FIG. 3. The transistor 400 is formed over the first well 202 and the second well 206, e.g., a p-well and an n-well, as described with respect to FIGS. 2 and 3.

The transistor 400 further includes a first S/D region 422 and a second S/D region 424, which are similar to the S/D regions 322 and 324 of FIG. 3. In this example, the transistor 400 includes two dummy S/D regions 432a and 432b, which are similar to the dummy S/D region 332 of FIG. 3. Like the dummy S/D region 332, the dummy S/D regions 432 are not coupled to conductive contacts. The dummy S/D regions 432a and 432b are between the first S/D region 422 and the second S/D region 424.

In this example, three gate stacks 212 are formed over the nanoribbons. A first gate stack 434 is formed over the nanoribbons, in a region between the first S/D region 422 and the dummy S/D region 432a. Two additional dummy gate stacks 436a and 436b are formed over the nanoribbons. The first dummy gate stack 436a is between the first dummy S/D region 432a and the second dummy S/D region 432b. The second dummy gate stack 436b is between the second dummy region 432b and the S/D region 424. Like the dummy gate 336 of FIG. 3, the dummy gates 436a and 436b are not coupled to conductive contacts.

Conductive contacts 426, 428, and 430 are coupled to the first S/D region 422, the first gate stack 434, and the second S/D region 424, respectively. The conductive contacts 426, 428, and 430 are similar to the conductive contacts 326, 328, and 330 of FIG. 3.

The second S/D region 424 is physically separated from the first S/D region 422 and the active gate 434, and thus forms an extended S/D region, or (if the S/D region 424 is a drain) an extended drain. The region 442 of the transistor 400 may be considered an extended drain region. The region 442 has a greater length (where length is measured in the x-direction in the coordinate system shown) than the region 342 in FIG. 3. The transistor 400 has a length 440, where the length 440 is measured from the first S/D region 422 (e.g., the center of the first S/D region 422) to the second S/D region 424 (e.g., the center of the second S/D region 424). The length 440 may be, for example, at least 100 nanometers, at least 150 nanometers, at least 200 nanometers, at least 300 nanometers, at least 400 nanometers, at least 500 nanometers, or a different length. The length 440 is greater than the length 340 of the transistor 300. FIG. 4 also illustrates a unit length 444, which may be the same as the unit length 344. The unit length 444 is a distance between adjacent S/D regions, e.g., a distance between the dummy S/D regions 432a and 432b, or a distance between the dummy S/D region 432b and the S/D region 424. The unit length 444 may be, e.g., at least 50 nanometers, at least 70 nanometers, at least 100 nanometers, at least 150 nanometers, at least 200 nanometers, etc.

Current flow through the transistor 400 is controlled by the contacts 426, 428, and 430. When a voltage is applied to the conductive contact 430, current may flow through the S/D region 424, the second well 206, and the first dummy S/D contact 432a. In other words, current may flow through the second well 206 in the extended drain region 442. In some cases, current may not flow through the nanoribbons in the region 442, or a minimal amount of current may flow through the nanoribbons in the region 442.

In some examples, a device may include both the transistor 300 and the transistor 400. For example, the conductive contact 430 coupled to the second S/D region 424 in the transistor 400 may receive an input voltage that is higher than an input voltage applied to the conductive contact 330 coupled to the second S/D region 324 in the transistor 300. The length of the extended drain region 342 or 442 may be related to the amount of voltage drop across the region, with a longer extended drain region (e.g., the region 442) having a greater voltage drop than a shorter extended drain region (e.g., the region 342).

While FIG. 3 includes one dummy S/D region 332 and one dummy gate 336, and FIG. 4 includes two dummy S/D regions 432a and 432b and two dummy gates 436a and 436b, a transistor with an extended gate may include three or more dummy S/D regions and three or more dummy gates, following a similar pattern to FIG. 4.

### Example CFET Architecture

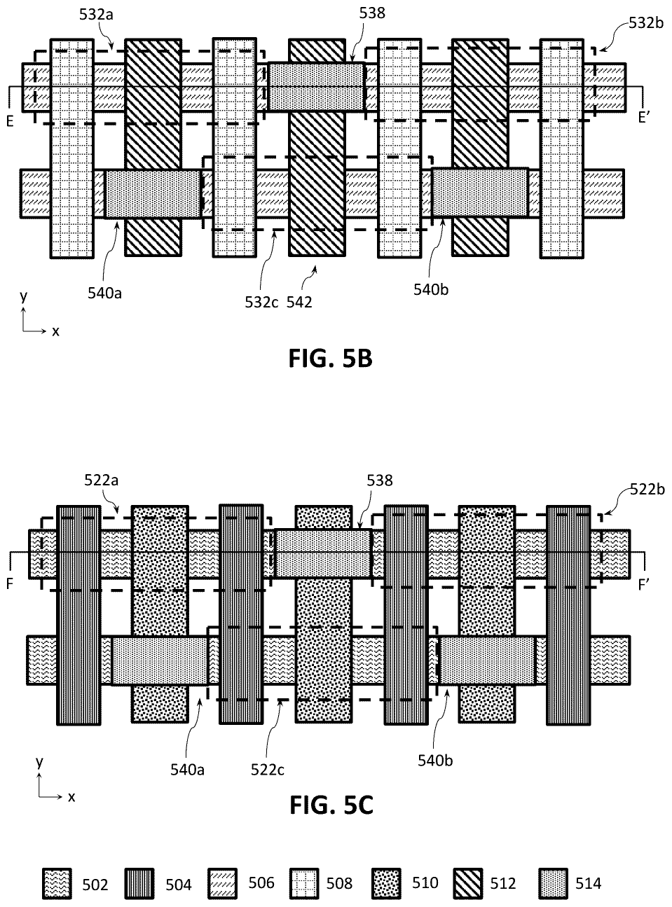

As noted above, an extended drain GAA transistor device may be implemented in device that also includes CFETs. FIGS. 5A-C illustrate different cross-sections through several transistors in a CFET device, according to some embodiments of the present disclosure.

A number of elements in FIG. 5 are illustrated in these figures with different patterns, with a legend showing the correspondence between the reference numerals and patterns being provided at the bottom of each drawing page containing these figures. For example, the legend illustrates that FIGS. 5A-5C use different patterns to show a first channel material 502, a first S/D material 504, a second channel material 506, a second S/D material 508, a first gate material 510, a second gate material 512, an isolation material 514, and an oxide 516.

The cross-sections illustrated in FIG. 5A-5C show cross-sections of two transistor layers with transistors of different types. FIG. 5A illustrates a first layer 520 with transistors 522a and 522b (referred to jointly as transistors 522) and a second layer 530 with transistors 532a and 532b (referred to jointly as transistors 532). For example, the transistors 522 are PMOS transistors, and the transistors 532 are NMOS transistors. Alternatively, the transistors 522 are NMOS transistors, and the transistors 532 are PMOS transistors. The materials used within the transistors 522 and 532 are typically different, e.g., the first channel material 502, first S/D material 504, and first gate material 510 may be selected from the materials used for PMOS transistors described with respect to FIG. 1, and the second channel material 506, second S/D material 508, and second gate material 512 may be selected from the materials used for NMOS transistors described with respect to FIG. 1. While two layers 520 and 530 are illustrated, in other embodiments, a different number of layers of transistors may included in the CFET device 500.

FIG. 5B illustrates a cross-section through the first layer 520, and in particular, through the plane CC′ in FIG. 5A. FIG. 5C illustrates a cross-section through the second layer 530, and in particular, through the plane DD′ in FIG. 5A. While two transistors are illustrated in each layer of FIG. 5A, it should be understood that each layer may include many more transistors, e.g., additional transistors in the x-direction in the coordinate system shown, and transistors in the y-direction in the coordinate system shown (e.g., viewed in different x-z cross-sections). For example, FIGS. 5B and 5C illustrate an additional row of transistors in the y-direction.

The transistors 522 and 532 are GAA transistors, and in particular, are nanowire or nanoribbon transistors. The channel materials 502 and 506 are arranged as a set of three nanoribbons, where each nanoribbon has an elongated structure. The nanoribbons may extend over a support structure, e.g., a substrate or other support structure as described above. The support structure may have a face extending in the x-y plane in the coordinate system shown. Each nanoribbon extends primarily in the x-direction in the coordinate system shown, e.g., parallel to the face of the support structure. The nanoribbons also extend in a direction parallel to the other nanoribbons in the stack. The second layer 530 is over the first layer 520, and the first layer 520 is under the second layer 530. The transistors 532 are stacked over the transistors 522. The support structure may be under the first layer 520, so that the first layer 520 is over the support structure, and the second layer 530 is over the support structure and over the first layer 520.

A source region and a drain region are formed around the ends of the nanoribbon channels. For example, a first S/D region 524a (e.g., a source region) and a second S/D region 524b (e.g., a drain region) are formed around the ends of the nanoribbons of the transistor 522a. A first S/D region 534a and a second S/D region 534b are formed around the ends of the nanoribbons of the transistor 532a. Gate stacks, which may include a gate electrode and a gate dielectric between the gate electrode and the channel material 502 or 506, are formed around the nanoribbons, between the S/D regions. For example, the gate stack 526 is formed around a middle portion of the nanoribbons of the transistor 522a, and the gate stack 536 is formed around a middle portion of the nanoribbons of the transistor 532a.

A layer of oxide 516 separates the lower layer 520 from the upper layer 530, and another layer of oxide 516 is below the lower layer 520. In addition, an isolation region 538 that includes the isolation material 514 is between adjacent transistors in each layer. In the first layer 520, the isolation region 538 is adjacent to the S/D region 524b of the transistor 522a, and the isolation region 538 is adjacent to another S/D region of the transistor 522b on the opposite side of the isolation material 514. In the second layer 530, the isolation region 538 is adjacent to the S/D region 534b of the transistor 532a, and the isolation region 538 is adjacent to another S/D region of the transistor 532b on the opposite side of the isolation region 538. Additional isolation regions formed from the isolation material 514 may be on the other sides of the transistors, e.g., adjacent to the S/D regions 524a and 534b. Additional dielectric material not specifically illustrated may be included, e.g., between S/D regions and gates.

As noted above, FIG. 5B illustrates a cross-section through the plane CC′ in FIG. 5A. FIG. 5A is the cross-section through the plane EE′ in FIG. 5B. FIG. 5B includes the transistors 532a and 532b. FIG. 5B further includes a third transistor 532c and a pair of isolation regions 540a and 540b on either side of the transistor 532c.

FIG. 5C illustrates a cross-section through the plane DD′ in FIG. 5A. FIG. 5A is the cross-section through the plane FF′ in FIG. 5C. FIG. 5C includes the transistors 522a and 522b. FIG. 5C further includes a third transistor 522c and another portion of the pair of isolation regions 540a and 540b from FIG. 5B, where the portions shown in FIG. 5C are on either side of the transistor 522c.

Example GAA Transistors with Extended Drain for CFET Implementations

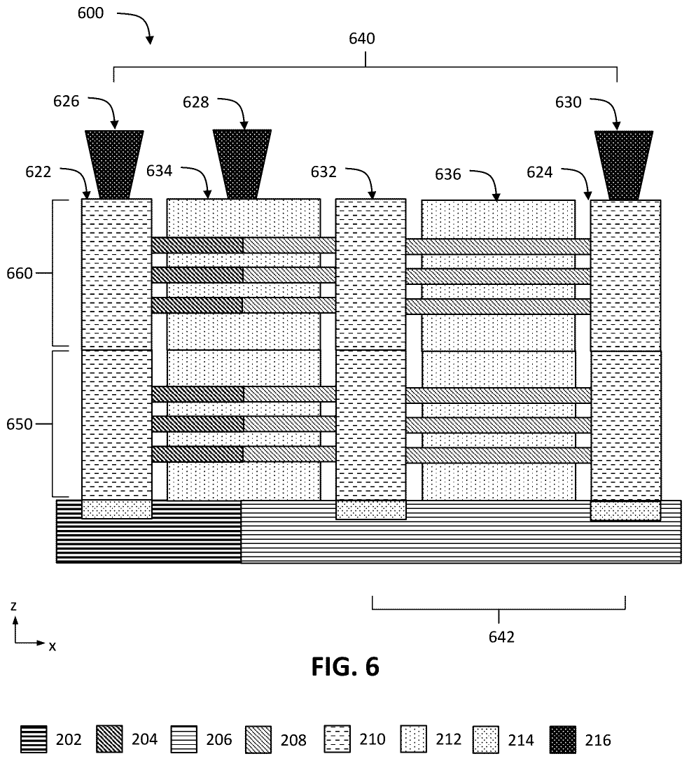

FIG. 6 is a cross-section of a GAA transistor with an extended drain that may be formed across multiple layers in a CFET device, according to some embodiments of the present disclosure. The transistor 600 includes two stacks of three nanoribbons each, where a first stack is formed in a first layer 650, and a second stack is formed in a second layer 660. The layers 650 and 660 may correspond to the layers 520 and 530 of FIG. 5, e.g., the layer 650 and 520 may be the same layer over a support structure (but in different regions of the device), and the layer 660 and 530 may be the same layer of the support structure and the first layer 650/520 (but in different regions of the device). The nanoribbon stacks in each layer 650 and 660 may be similar to the nanoribbons 320 of FIG. 3. While three nanoribbons are included in each layer 650 and 660, any number of nanoribbons may be included. The transistor 600 is formed over the first well 202 and the second well 206, e.g., a p-well and an n-well, as described with respect to FIGS. 2 and 3. The nanoribbon stacks and the wells 202 and 206 may be doped as described with respect to FIG. 2. For example, the well doping matches the doping along the nanoribbons, which may be doped during the same implantation process. Unlike the arrangement shown in FIG. 5, there is not an oxide layer between the two layers 650 and 660.

The transistor 600 further includes a first S/D region 622 and a second S/D region 624. The S/D regions 622 and 624 are similar to the S/D regions 322 and 324 of FIG. 3, except here, they extend through the two layers 650 and 650 and across two stacks of nanoribbons. In this example, the transistor 600 includes a dummy S/D region 632, which is similar to the dummy S/D region 332 of FIG. 3, except that the dummy S/D region 632 also extends through the two stacks of nanoribbons in the layers 650 and 660. Like the dummy S/D region 332, the dummy S/D region 632 is not coupled to a conductive contact. The dummy S/D region 632 is between the first S/D region 622 and the second S/D region 624.

In this example, two gate stacks 212 are formed over the nanoribbons. A first gate stack 634 is formed over the nanoribbons, in a region between the first S/D region 622 and the dummy S/D region 632. A second gate stack 636, which is a dummy gate stack, is formed over the nanoribbons. The dummy gate stack 636 is between the dummy S/D region 632 and the second S/D region 624. Like the dummy gate 336 of FIG. 3, the dummy gate 636 is not coupled to a conductive contact. While FIG. 6 includes one dummy S/D region 632 and one dummy gate 636, in other embodiments, two or more dummy S/D regions and dummy gates may be included in the extended drain region 642, e.g., as described with respect to FIG. 4.

Conductive contacts 626, 628, and 630 are coupled to the first S/D region 622, the first gate stack 634, and the second S/D region 624, respectively. The conductive contacts 626, 628, and 630 are similar to the conductive contacts 326, 328, and 330 of FIG. 3.

The second S/D region 624 is physically separated from the first S/D region 622 and the active gate 634, and thus forms an extended S/D region, or (if the S/D region 624 is a drain) an extended drain. The region 642 of the transistor 600 may be considered an extended drain region. The transistor 600 has a length 640, where the length 640 is measured from the first S/D region 622 (e.g., the center of the first S/D region 622) to the second S/D region 624 (e.g., the center of the second S/D region 424). The length 640 may be, for example, at least 100 nanometers, at least 150 nanometers, at least 200 nanometers, at least 300 nanometers, or a different length. The transistor 600 may also have a height measured in the z-direction in the coordinate system shown, where the height includes the height of the layers 650 and 660. The height of the transistor 600 may be greater than the height of the transistor 300. The extended height may result in a greater voltage drop across the extended drain region 342 of the transistor 300. The transistor 600 may also have a unit length, which a length between adjacent S/D regions, as described with respect to FIG. 3 and FIG. 4. For example, the unit length is a distance between the first S/D region 622 and the dummy S/D region 632, and/or a distance between the dummy S/D region 632 and the second S/D region 624. The unit length of the transistor 600 may be, e.g., at least 50 nanometers, at least 70 nanometers, at least 100 nanometers, at least 150 nanometers, at least 200 nanometers, etc.

Current flow through the transistor 600 is controlled by the contacts 626, 628, and 630. When a voltage is applied to the conductive contact 630, current may flow through the S/D region 624, the second well 206, and the dummy S/D region 632. In other words, current may flow through the second well 206 in the extended drain region 642. In some cases, current may not flow through the nanoribbons in the region 642, or a minimal amount of current may flow through the nanoribbons in the region 642.

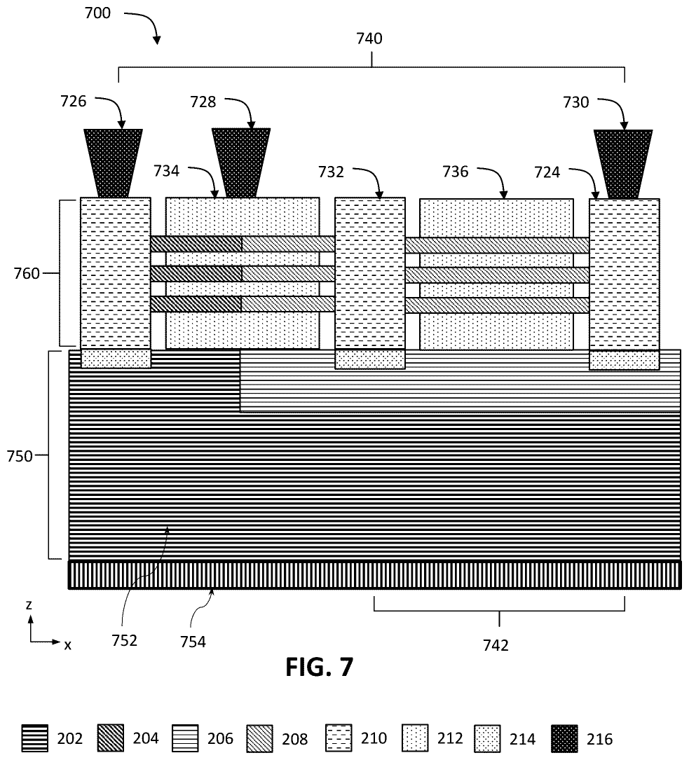

FIG. 7 is a cross-section of a GAA transistor 700 with an extended drain that may be formed over a fin pedestal in a CFET device, according to some embodiments of the present disclosure. The transistor 700 includes a fin-shaped pedestal 752 in a lower layer 750, and a stack of nanoribbons in an upper layer 760. The layers 750 and 760 may correspond to the layers 520 and 530 of FIG. 5, e.g., the layer 750 and 520 may be the same layer over a support structure (but in different regions of the device), and the layer 760 and 530 may be the same layer of the support structure and the first layer 750/720 (but in different regions of the device). In this example, in the portion of the device where the extended drain transistors are formed, rather than having two stacks of nanoribbons stacked on top of each other (as shown in FIGS. 5 and 6), a fin-shaped pedestal 752 with doped wells is formed in the lower layer. The pedestal 752 may be relatively narrow in the y-direction in the coordinate system shown, e.g., the pedestal 752 has a fin shape that extends primarily in the x-direction. The pedestal 752 is formed over an oxide layer 754, which may be the same as the oxide layer 516 below the lower layer 520 in FIG. 5. The pedestal 752 includes the first well 202 and the second well 206, e.g., a p-well and an n-well, as described with respect to FIGS. 2 and 3. The nanoribbon stack in the layer 760 is formed over the first well 202 and the second well 206. The nanoribbon stack may be similar to the nanoribbons 320 of FIG. 3. The nanoribbons and the wells 202 and 206 in the pedestal 752 may be doped as described with respect to FIG. 2. For example, the well doping in the pedestal 752 matches the doping along the nanoribbons, which may be doped during the same implantation process.

The transistor 700 further includes a first S/D region 722 and a second S/D region 724. The S/D regions 722 and 724 are similar to the S/D regions 322 and 324 of FIG. 3. In this example, the transistor 700 includes a dummy S/D region 732, which is similar to the dummy S/D region 332 of FIG. 3. Like the dummy S/D region 332, the dummy S/D region 732 is not coupled to a conductive contact. The dummy S/D region 732 is between the first S/D region 722 and the second S/D region 724.

In this example, two gate stacks 212 are formed over the nanoribbons. A first gate stack 734 is formed over the nanoribbons, in a region between the first S/D region 722 and the dummy S/D region 732. A second gate stack 736, which is a dummy gate stack, is formed over the nanoribbons between the dummy S/D region 732 and the second S/D region 724. Like the dummy gate 336 of FIG. 3, the dummy gate 736 is not coupled to a conductive contact. While FIG. 7 includes one dummy S/D region 732 and one dummy gate 736, in other embodiments, two or more dummy S/D regions and dummy gates may be included in the extended drain region 742, e.g., as described with respect to FIG. 4.

Conductive contacts 726, 728, and 730 are coupled to the first S/D region 722, the first gate stack 734, and the second S/D region 724, respectively. The conductive contacts 726, 728, and 730 are similar to the conductive contacts 326, 328, and 330 of FIG. 3.

The second S/D region 724 is physically separated from the first S/D region 722 and the active gate 734, and thus forms an extended S/D region, or (if the S/D region 724 is a drain) an extended drain. The region 742 of the transistor 700 may be considered an extended drain region. The transistor 700 has a length 740, where the length 740 is measured from the first S/D region 722 (e.g., the center of the first S/D region 722) to the second S/D region 724 (e.g., the center of the second S/D region 724). The length 740 may be, for example, at least 100 nanometers, at least 150 nanometers, at least 200 nanometers, at least 300 nanometers, or a different length. The transistor 700 may also have a unit length, which a length between adjacent S/D regions, as described with respect to FIG. 3 and FIG. 4. For example, the unit length is a distance between the first S/D region 722 and the dummy S/D region 732, and/or a distance between the dummy S/D region 732 and the second S/D region 724. The unit length of the transistor 700 may be, e.g., at least 50 nanometers, at least 70 nanometers, at least 100 nanometers, at least 150 nanometers, at least 200 nanometers, etc.

Current flow through the transistor 700 is controlled by the contacts 726, 728, and 730. When a voltage is applied to the conductive contact 730, current may flow through the S/D region 724, the second well 206 in the pedestal 752, and the dummy S/D region 732. In other words, current may flow through the second well 206 in the extended drain region 742. In some cases, current may not flow through the nanoribbons in the region 742, or a minimal amount of current may flow through the nanoribbons in the region 742.

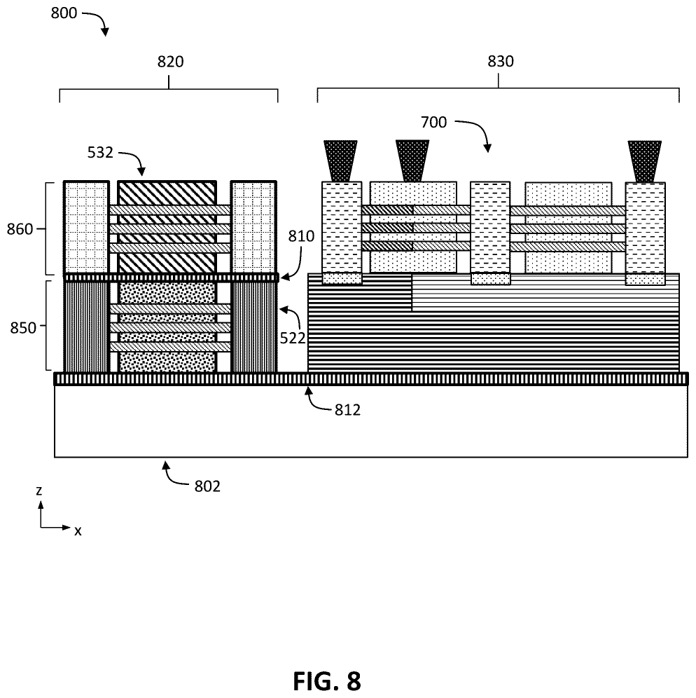

FIG. 8 is a cross-section illustrating the GAA transistor of FIG. 7 alongside a CFET stack, according to some embodiments of the present disclosure. In this example, a device 800 includes a CFET region 820 and an extended drain transistor region 830. The device further includes a first layer 850, which corresponds to the layer 520 in FIG. 5 and the layer 750 in FIG. 7, and a second layer 860, which corresponds to the layer 530 in FIG. 5 and the layer 760 in FIG. 7.

The CFET region 820 includes the transistors 522 and 532 of FIG. 5, i.e., a stack of CFET transistors. The transistor 522 is in the layer 850, and the transistor 532 is in the layer 860. While one stack of two transistors is illustrated in FIG. 8, it should be understood that the CFET region 820 may include many similar transistor stacks.

The extended drain transistor region 830 includes the extended drain transistor 700. The pedestal 752 is in the layer 850, and the transistor 700 is in the layer 860. While one example extended drain transistor 700 is illustrated in FIG. 8, it should be understood that the extended drain transistor region 830 may include many similar transistors. Furthermore, in other embodiments, the transistor 700 and pedestal 752 may be replaced with the transistor 600, shown in FIG. 6.

The device 800 is formed over a support structure 802. The support structure 802 is under both the CFET region 820 and the extended drain transistor region 830. A first oxide layer 812 is over the support structure 802, and below the CFET region 820 and the extended drain transistor region 830. The CFET region 820 includes a second oxide layer 810 between the two transistors 522 and 532. The second oxide layer 810 is not included in the extended drain transistor region 830, i.e., the transistor 700 is formed directly over the pedestal 752 with the n-well and the p-well, without an intervening oxide layer.

### Example Devices

The circuit devices with extended drain transistors disclosed herein may be included in any suitable electronic device. FIGS. 9-13 illustrate various examples of apparatuses that may include the one or more transistors disclosed herein, which may have been fabricated using the processes disclosed herein.

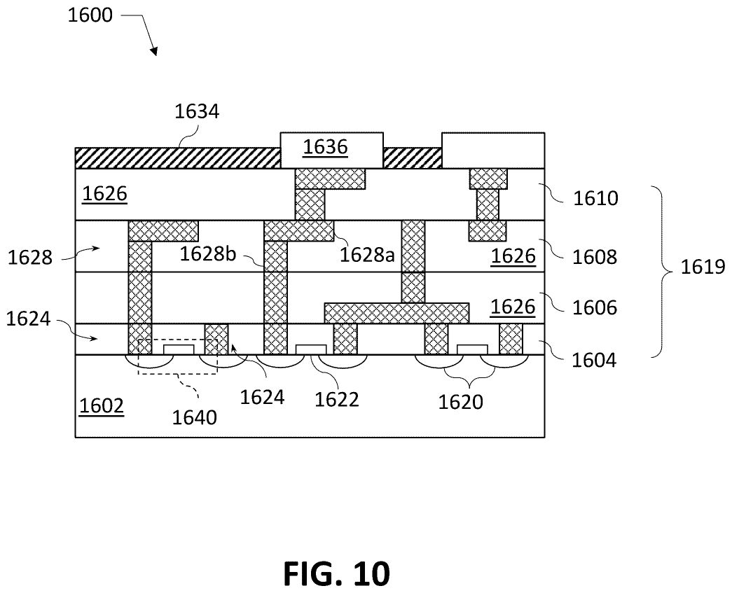

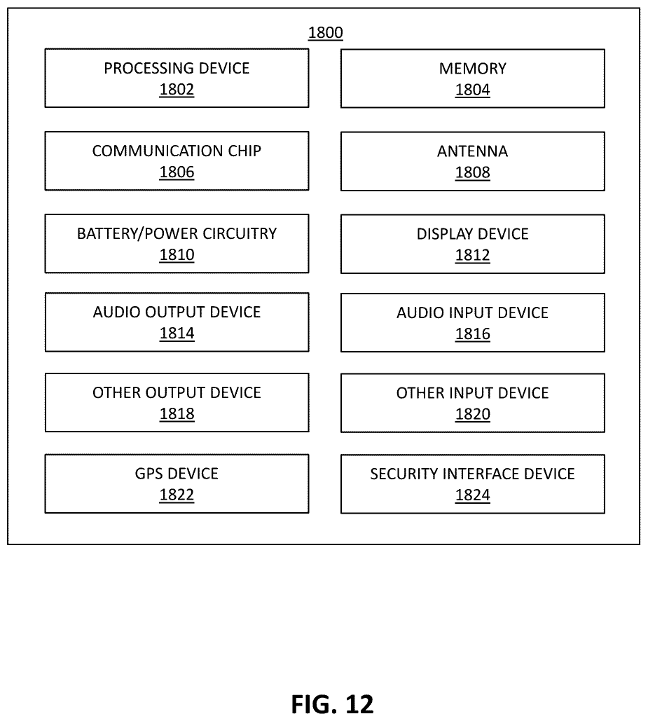

FIGS. 9A and 9B are top views of a wafer and dies that include one or more IC structures including one or more extended drain transistors in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIGS. 1-8, or any further embodiments of the IC structures described herein). After the fabrication of the semiconductor product is complete (e.g., after manufacture of one or more IC structures with one or more of the transistors as described herein, included in a particular electronic component, e.g., in a transistor or in a memory device), the wafer 1500 may undergo a singulation process in which each of the dies 1502 is separated from one another to provide discrete “chips” of the semiconductor product. In particular, devices that include one or more of the transistors as disclosed herein may take the form of the wafer 1500 (e.g., not singulated) or the form of the die 1502 (e.g., singulated). The die 1502 may include one or more transistors (e.g., one or more of the transistors 1640 of FIG. 10, discussed below) and/or supporting circuitry to route electrical signals to the transistors, as well as any other IC components (e.g., one or more of the extended drain transistors described herein). In some embodiments, the wafer 1500 or the die 1502 may include a memory device (e.g., an SRAM device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 12) or other logic that is configured to store information in the memory devices or execute instructions stored in the memory array.

FIG. 10 is a cross-sectional side view of an IC device 1600 that may include one or more extended drain transistors in accordance with any of the embodiments disclosed herein. The IC device 1600 may be formed on a substrate 1602 (e.g., the wafer 1500 of FIG. 9A) and may be included in a die (e.g., the die 1502 of FIG. 9B). The substrate 1602 may be any substrate as described herein. The substrate 1602 may be part of a singulated die (e.g., the dies 1502 of FIG. 9B) or a wafer (e.g., the wafer 1500 of FIG. 9A).

The IC device 1600 may include one or more device layers 1604 disposed on the substrate 1602. The device layer 1604 may include features of one or more transistors 1640 (e.g., metal-oxide-semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 10 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross-section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The IC device 1600 may include one or more extended drain transistors at any suitable location in the IC device 1600.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group Ill-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 10 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 10). Although a particular number of interconnect layers 1606-1610 is depicted in FIG. 10, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 10. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 10. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

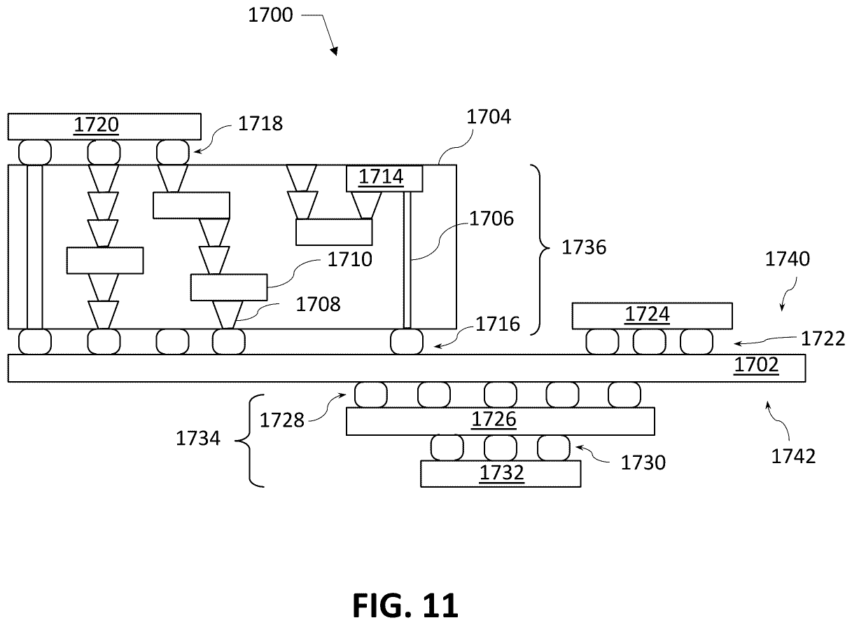

FIG. 11 is a cross-sectional side view of an IC device assembly 1700 that may include components having or being associated with (e.g., being electrically connected by means of) one or more extended drain transistors in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. In particular, any suitable ones of the components of the IC device assembly 1700 may include one or more of the extended drain transistors disclosed herein.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 11 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 11), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 11, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 9B), an IC device (e.g., the IC device 1600 of FIG. 10), or any other suitable component. In some embodiments, the IC package 1720 may include one or more extended drain transistors, as described herein. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 11, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group Ill-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 11 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 12 is a block diagram of an example computing device 1800 that may include one or more components including one or more extended drain transistors in accordance with any of the embodiments disclosed herein. For example, any suitable ones of the components of the computing device 1800 may include a die (e.g., the die 1502 of FIG. 9B) having one or more transistors as described herein. Any one or more of the components of the computing device 1800 may include, or be included in, an IC device 1600 (FIG. 10). Any one or more of the components of the computing device 1800 may include, or be included in, an IC device assembly 1700 (FIG. 11).

A number of components are illustrated in FIG. 12 as included in the computing device 1800, but any one or more of these components may be omitted or duplicated, as suitable for the application. In some embodiments, some or all of the components included in the computing device 1800 may be attached to one or more motherboards. In some embodiments, some or all of these components are fabricated onto a single system-on-a-chip (SoC) die.

Additionally, in various embodiments, the computing device 1800 may not include one or more of the components illustrated in FIG. 11, but the computing device 1800 may include interface circuitry for coupling to the one or more components. For example, the computing device 1800 may not include a display device 1806, but may include display device interface circuitry (e.g., a connector and driver circuitry) to which a display device 1806 may be coupled. In another set of examples, the computing device 1800 may not include an audio input device 1824 or an audio output device 1808 but may include audio input or output device interface circuitry (e.g., connectors and supporting circuitry) to which an audio input device 1824 or audio output device 1808 may be coupled.

The computing device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 1800 may include a memory 1804, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random-access memory (eDRAM) or spin transfer torque magnetic random-access memory (STT-MRAM).

In some embodiments, the computing device 1800 may include a communication chip 1812 (e.g., one or more communication chips). For example, the communication chip 1812 may be configured for managing wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The computing device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The computing device 1800 may include battery/power circuitry 1814. The battery/power circuitry 1814 may include one or more energy storage devices (e.g., batteries or capacitors) and/or circuitry for coupling components of the computing device 1800 to an energy source separate from the computing device 1800 (e.g., AC line power).

The computing device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display, for example.

The computing device 1800 may include an audio output device 1808 (or corresponding interface circuitry, as discussed above). The audio output device 1808 may include any device that generates an audible indicator, such as speakers, headsets, or earbuds, for example.

The computing device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The computing device 1800 may include a GPS device 1818 (or corresponding interface circuitry, as discussed above). The GPS device 1818 may be in communication with a satellite-based system and may receive a location of the computing device 1800, as known in the art.

The computing device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The computing device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1800 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1800 may be any other electronic device that processes data.

### Select Examples

The following paragraphs provide various examples of the embodiments disclosed herein.

Example 1 provides an integrated circuit (IC) device including a plurality of nanoribbons arranged in a stack, each nanoribbon in the stack extending in a direction parallel to other nanoribbons in the stack; a first source or drain region coupled to the plurality of nanoribbons at a first end of the stack; a second source or drain region coupled to the plurality of nanoribbons at a second end of the stack, the second end opposite the first end; a third source or drain region coupled to the plurality of nanoribbons, the third source or drain region between the first source or drain region and the second source or drain region; a first contact coupled to the first source or drain region; and a second contact coupled to the second source or drain region.

Example 2 provides the IC device of example 1, where the third source or drain region is not coupled to a contact.

Example 3 provides the IC device of example 1 or 2, further including a conductive region coupled to the plurality of nanoribbons, the conductive region between the first source or drain region and the third source or drain region; and a third contact coupled to the conductive region.

Example 4 provides the IC device of example 3, further including a second conductive region coupled to the plurality of nanoribbons, the second conductive region between the third source or drain region and the second source or drain region, where the second conductive region is not coupled to a contact.

Example 5 provides the IC device of any of the preceding examples, where one of the plurality of nanoribbons includes a first portion proximate to the first source or drain region, the first portion including a first dopant; and a second portion proximate to the third source or drain region, the second portion including a second dopant.

Example 6 provides the IC device of example 5, where the one of the plurality of nanoribbons further includes a third portion proximate to the second source or drain region, where the third portion includes the second dopant.

Example 7 provides the IC device of any of the preceding examples, further including a fin-shaped region below the plurality of nanoribbons, the fin-shaped region extending in the direction parallel to the nanoribbons.

Example 8 provides the IC device of example 7, where the fin-shaped region includes a first portion having a first dopant, the first portion under the first source or drain region; and a second portion having a second dopant, the second portion under the third source or drain region and the second source or drain region.

Example 9 provides the IC device of any of the preceding examples, further including a fourth source or drain region coupled to the plurality of nanoribbons, the fourth source or drain region between the third source or drain region and the second source or drain region.

Example 10 provides the IC device of any of the preceding examples, where a distance between the first source or drain region and the second source or drain region is at least 100 nanometers.

Example 11 provides an integrated circuit (IC) device including a first device region including a first transistor in a first layer of the IC device, the first transistor including first source and drain regions having a first material; and a second transistor including second source and drain regions having a second material different from the first material, the second transistor stacked over the first transistor, and the second transistor in a second layer of the IC device, the second layer over the first layer; and a second device region including a third transistor in the second layer of the IC device, the third transistor including a semiconductor region having a first end and a second end; a first source or drain region coupled to the first end of the semiconductor region; a second source or drain region coupled to the second end of the semiconductor region; and a third source or drain region coupled to the semiconductor region, the third source or drain region between the first source or drain region and the second source or drain region.

Example 12 provides the IC device of example 11, the third transistor further including a first contact coupled to the first source or drain region; and a second contact coupled to the second source or drain region, where the third source or drain region is not coupled to a contact.

Example 13 provides the IC device of example 11 or 12, the second device region further including a fin-shaped region extending under the third transistor in the first layer of the IC device.

Example 14 provides the IC device of example 13, the fin-shaped region including a first portion under the first source or drain region of the third transistor, the first portion including a first dopant; and a second portion under the third source or drain region and the second source or drain region of the third transistor, the second portion including a second dopant.

Example 15 provides the IC device of any of examples 11-14, the first device region further including a third layer between the first layer and the second layer, the third layer including oxygen, where the third layer including oxygen is not present in the second device region.

Example 16 provides an integrated circuit (IC) device including a first stack of nanoribbons, each nanoribbon in the first stack extending in a direction parallel to other nanoribbons in the first stack; a second stack of nanoribbons, each nanoribbon in the second stack extending in a direction parallel to other nanoribbons in the second stack and in the direction parallel to nanoribbons in the first stack; a first source or drain region coupled to the first stack of nanoribbons and the second stack of nanoribbons at a first end of the first stack and the second stack; a second source or drain region coupled to the first stack of nanoribbons and the second stack of nanoribbons at a second end of the first stack and the second stack, the second end opposite the first end; a third source or drain region coupled to the first stack of nanoribbons and the second stack of nanoribbons, the third source or drain region between the first source or drain region and the second source or drain region; a first contact coupled to the first source or drain region; and a second contact coupled to the second source or drain region.

Example 17 provides the IC device of example 16, where the second stack of nanoribbons is over the first stack of nanoribbons.

Example 18 provides the IC device of example 16 or 17, where the third source or drain region is not coupled to a contact.

Example 19 provides the IC device of any of examples 16-18, further including a fourth source or drain region coupled to the first stack of nanoribbons and the second stack of nanoribbons, the fourth source or drain region between the third source or drain region and the second source or drain region.

Example 20 provides the IC device of any of examples 16-19, where the first stack of nanoribbons and the second stack of nanoribbons are in a first device region, the IC device further including a second device region, the second device region including a complementary field-effect-transistor.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device comprising:
a plurality of nanoribbons arranged in a stack, each nanoribbon in the stack extending in a direction parallel to other nanoribbons in the stack;
a first source or drain region coupled to the plurality of nanoribbons at a first end of the stack;
a second source or drain region coupled to the plurality of nanoribbons at a second end of the stack, the second end opposite the first end;
a third source or drain region coupled to the plurality of nanoribbons, the third source or drain region between the first source or drain region and the second source or drain region;
a first contact coupled to the first source or drain region; and
a second contact coupled to the second source or drain region.

2. The IC device of claim 1, wherein the third source or drain region is not coupled to a contact.

3. The IC device of claim 1, further comprising:
a conductive region coupled to the plurality of nanoribbons, the conductive region between the first source or drain region and the third source or drain region; and
a third contact coupled to the conductive region.

4. The IC device of claim 3, further comprising:
a second conductive region coupled to the plurality of nanoribbons, the second conductive region between the third source or drain region and the second source or drain region, wherein the second conductive region is not coupled to a contact.

5. The IC device of claim 1, wherein one of the plurality of nanoribbons comprises:
a first portion proximate to the first source or drain region, the first portion comprising a first dopant; and
a second portion proximate to the third source or drain region, the second portion comprising a second dopant.

6. The IC device of claim 5, wherein the one of the plurality of nanoribbons further comprises:
a third portion proximate to the second source or drain region, wherein the third portion comprises the second dopant.

7. The IC device of claim 1, further comprising a fin-shaped region below the plurality of nanoribbons, the fin-shaped region extending in the direction parallel to the nanoribbons.

8. The IC device of claim 7, wherein the fin-shaped region comprises:
a first portion having a first dopant, the first portion under the first source or drain region; and
a second portion having a second dopant, the second portion under the third source or drain region and the second source or drain region.

9. The IC device of claim 1, further comprising a fourth source or drain region coupled to the plurality of nanoribbons, the fourth source or drain region between the third source or drain region and the second source or drain region.

10. The IC device of claim 1, wherein a distance between the first source or drain region and the second source or drain region is at least 100 nanometers.

11. An integrated circuit (IC) device comprising:
a first device region comprising:
a first transistor in a first layer of the IC device, the first transistor comprising first source and drain regions having a first material; and
a second transistor comprising second source and drain regions having a second material different from the first material, the second transistor stacked over the first transistor, and the second transistor in a second layer of the IC device, the second layer over the first layer; and
a second device region comprising a third transistor in the second layer of the IC device, the third transistor comprising:
a semiconductor region having a first end and a second end;
a first source or drain region coupled to the first end of the semiconductor region;
a second source or drain region coupled to the second end of the semiconductor region; and
a third source or drain region coupled to the semiconductor region, the third source or drain region between the first source or drain region and the second source or drain region.

12. The IC device of claim 11, the third transistor further comprising:
a first contact coupled to the first source or drain region; and
a second contact coupled to the second source or drain region, wherein the third source or drain region is not coupled to a contact.

13. The IC device of claim 11, the second device region further comprising a fin-shaped region extending under the third transistor in the first layer of the IC device.

14. The IC device of claim 13, the fin-shaped region comprising:
a first portion under the first source or drain region of the third transistor, the first portion comprising a first dopant; and
a second portion under the third source or drain region and the second source or drain region of the third transistor, the second portion comprising a second dopant.

15. The IC device of claim 11, the first device region further comprising a third layer between the first layer and the second layer, the third layer comprising oxygen, wherein the third layer comprising oxygen is not present in the second device region.

16. An integrated circuit (IC) device comprising:
a first stack of nanoribbons, each nanoribbon in the first stack extending in a direction parallel to other nanoribbons in the first stack;
a second stack of nanoribbons, each nanoribbon in the second stack extending in a direction parallel to other nanoribbons in the second stack and in the direction parallel to nanoribbons in the first stack;
a first source or drain region coupled to the first stack of nanoribbons and the second stack of nanoribbons at a first end of the first stack and the second stack;
a second source or drain region coupled to the first stack of nanoribbons and the second stack of nanoribbons at a second end of the first stack and the second stack, the second end opposite the first end;
a third source or drain region coupled to the first stack of nanoribbons and the second stack of nanoribbons, the third source or drain region between the first source or drain region and the second source or drain region;
a first contact coupled to the first source or drain region; and
a second contact coupled to the second source or drain region.

17. The IC device of claim 16, wherein the second stack of nanoribbons is over the first stack of nanoribbons.

18. The IC device of claim 16, wherein the third source or drain region is not coupled to a contact.

19. The IC device of claim 16, further comprising a fourth source or drain region coupled to the first stack of nanoribbons and the second stack of nanoribbons, the fourth source or drain region between the third source or drain region and the second source or drain region.

20. The IC device of claim 16, wherein the first stack of nanoribbons and the second stack of nanoribbons are in a first device region, the IC device further comprising a second device region, the second device region comprising a complementary field-effect-transistor.
